(19) United States
(12) Patent Application Publication
(10) Pub. No.: US 2024/0222128 A1
(43) Pub. Date: Jul. 4, 2024

(54) METHODS TO IMPROVE PRODUCTIVITY OF ADVANCED CVD W GAPFILL PROCESS

(71) Applicant: Applied Materials, Inc., Santa Clara, CA (US)

(72) Inventors: Mingrui ZHAO, Newark, CA (US); Peiqi WANG, Campbell, CA (US); Kai WU, Palo Alto, CA (US); Harpreet SINGH, Tracy, CA (US); Michael C. KUTNEY, Santa Clara, CA (US)

(21) Appl. No.: 18/558,388

(22) PCT Filed: May 6, 2021
(86) PCT No.: PCT/CN2021/091929

§ 371 Date: Nov. 1, 2023

(51) Int. Cl. H01L 21/285; C23C 16/02; C23C 16/06; C23C 16/44; C23C 16/455; C23C 16/52; H01L 21/768

(52) U.S. Cl. CPC H01L 21/28506; C23C 16/0281; C23C 16/06; C23C 16/4405; C23C 16/4554; C23C 16/52; H01L 21/76879

(57) ABSTRACT

Embodiments herein are generally directed to electronic device manufacturing and, more particularly, to systems and methods for forming substantially void-free and seam-free tungsten features in a semiconductor device manufacturing scheme. In one embodiment, a substrate processing system features a processing chamber and a gas delivery system fluidly coupled to the processing chamber. The gas delivery system includes a first radical generator for use in a differential inhibition treatment process and a second radical generator for use in a chamber clean process. The processing system is configured to periodically condition the first radial generator by forming a plasma of a relatively low amount of a halogen-based gas.

### BACKGROUND

### Field

Embodiments herein are directed to systems and methods used in electronic device manufacturing, and more particularly, to systems and methods used for forming tungsten features in a semiconductor device.

### Description of the Related Art

Tungsten (W) is widely used in integrated circuit (IC) device manufacturing to form conductive features where relatively low electrical resistance and relativity high resistance to electromigration are desired. For example, tungsten may be used as a metal fill material to form source contacts, drain contacts, metal gate fill, gate contacts, interconnects (e.g., horizontal features formed in a surface of a dielectric material layer), and vias (e.g., vertical features formed through a dielectric material layer to connect other interconnect features disposed there above and there below). Due to its relativity low resistivity, tungsten is also commonly used to form bit lines and word lines used to address individual memory cells in a memory cell array of a dynamic random-access memory (DRAM) device.

As circuit densities increase and device features continue to shrink to meet the demands of the next generation of semiconductor devices, reliably producing tungsten features has become increasingly challenging. Issues such as voids and seams formed during a conventional tungsten deposition process become amplified with decreasing feature size and can detrimentally affect the performance and reliability of a device or even render a device inoperable.

Accordingly, what is needed in the art are processing systems and methods that solve the problems described above.

### SUMMARY

Embodiments herein are generally directed electronic device manufacturing and, more particularly, to systems and methods for forming substantially void-free and seam-free tungsten features in a semiconductor device-manufacturing scheme. In some embodiments, the systems and methods described herein provide a single-chamber processing solution with reduced substrate processing variability and increased substrate processing throughput to facilitate reliable integration of seam-free tungsten gapfill into a high-volume manufacturing line.

In one embodiment, a substrate processing system includes a processing chamber, including a chamber lid assembly, one or more chamber sidewalls, and a chamber base that collectively define a processing volume. The processing system further includes a gas delivery system fluidly coupled to the processing chamber, the gas delivery system including a first radical generator and a second radical generator; and a non-transitory computer readable medium having instructions stored thereon for performing a method of processing a plurality of substrates when executed by a processor. The method includes: (a) receiving a substrate into the processing volume; (b) exposing the substrate to an activated treatment gas, the activated treatment gas including an effluent of a treatment plasma formed in the first radical generator; (c) exposing the substrate to a first tungsten-containing precursor and a first reducing agent to deposit a tungsten gapfill material; (d) transferring the substrate out of the processing volume; (e) before or after (a), conditioning the first radical generator; and (f) repeating (a)-(e) when a number of sequentially processed substrates is less than or equal to a threshold value. Conditioning the first radical generator includes: (i) flowing a conditioning gas into the first radical generator, the conditioning gas including a halogen-based component; and (ii) igniting and maintaining a conditioning plasma of the conditioning gas for a first period of time.

In one embodiment, a method of processing a substrate includes: (a) receiving a substrate into a processing volume of a processing system; (b) exposing the substrate to an activated treatment gas; (c) exposing the substrate to a first tungsten-containing precursor and a first reducing agent; (d) transferring the substrate out of the processing volume; and (e) before or after (a), conditioning the first radical generator; and (f) repeating (a)-(e) when a number of sequentially processed substrates is less than or equal to a threshold value. In one embodiment, the processing system used to perform the method includes: a processing chamber including a chamber lid assembly, one or more chamber sidewalls, and a chamber base that collectively define the processing volume; and a gas delivery system fluidly coupled to the processing chamber, the gas delivery system including a first radical generator and a second radical generator. In one embodiments, conditioning the first radical generator includes: (i) flowing a conditioning gas into the first radical generator, the conditioning gas including a halogen-based component; and (ii) igniting and maintaining a conditioning plasma of the conditioning gas for a first period of time. In some embodiments, the activated treatment gas includes an effluent of a treatment plasma formed in the first radical generator.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIGS. 1A-1B are schematic sectional views of a portion of a substrate illustrating undesirable voiding or seaming in conventionally formed tungsten features.

FIG. 2A is a schematic side view of a processing system that may be used to implement the methods set forth herein, according to one embodiment.

FIG. 2B is a close-up sectional view of a portion of the processing system shown in FIG. 2A, according to one embodiment.

FIG. 3 is a diagram illustrating a substrate processing method, according to one embodiment, which may be performed using the processing system of FIGS. 2A-2B.

FIGS. 4A-4D are schematic sectional views of a portion of a substrate illustrating various aspects of the method set forth in FIG. 3.

FIG. 5 is a diagram illustrating a substrate processing method, according to another embodiment, which may be performed using the processing system of FIGS. 2A-2B.

FIGS. 6A-6D are schematic sectional views of a portion of a substrate illustrating various aspects of the method set forth in FIG. 5.

FIGS. 7A-7B are graphs illustrating within-substrate and substrate-to-substrate processing results for film layers formed using the methods set forth herein.

FIG. 8 is a schematic plan view of an exemplary multi-chamber processing system that may be used to perform the methods set forth herein, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed electronic device manufacturing and, more particularly, to systems and methods for forming substantially void-free and seam-free tungsten features in a semiconductor device manufacturing scheme.

Typically, the tungsten features in an IC device are formed using a damascene (metal inlay) manufacturing process flow. The damascene process flow begins with depositing a layer of dielectric material on the surface of the substrate, patterning the dielectric layer to form a plurality of openings, and depositing a layer of tungsten material onto the surface of the dielectric layer to fill the openings. Often, a layer of barrier or adhesion material, such as titanium nitride (TIN), is deposited to line the openings before deposition of the tungsten layer. Deposition of the barrier layer and tungsten layer creates an overburden of barrier and tungsten material on the field of the substrate, which is then removed by use of a chemical mechanical polishing (CMP) process.

The CMP process uses a combination of chemical and mechanical activity to planarize the tungsten overburden from the field, which is provided, at least in part, by a polishing fluid. Typical tungsten CMP polishing fluids comprise an aqueous solution that includes one or more chemically active components and suspended abrasive components, e.g., nanoparticles, to form a polishing slurry. The chemically active components soften the tungsten surface, e.g., by oxidizing the surface to form a thin layer of tungsten oxide, and the abrasive components polish (remove) the tungsten oxide to expose tungsten there beneath. The cycle of oxidation and polishing continues throughout the CMP process until the tungsten overburden is cleared from the field of the dielectric layer leaving the embedded tungsten features.

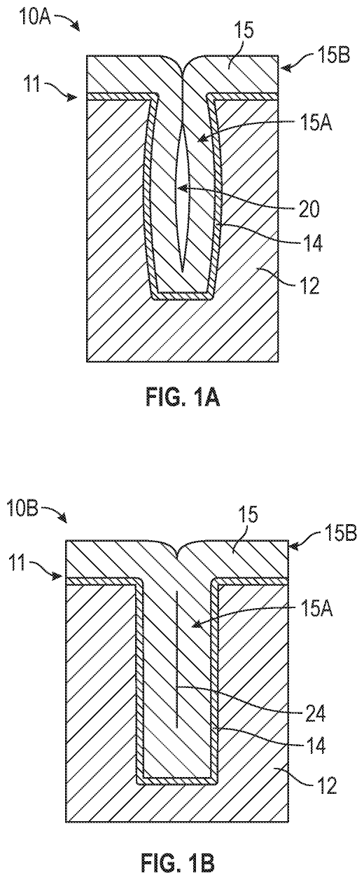

Typically, tungsten deposited using conventional methods is highly conformal to the underlying patterned surface. Unfortunately, as device features shrink and aspect ratios increase, the formation of undesirable voids and seams in tungsten features formed using conformal tungsten deposition methods is largely unavoidable. The resulting undesirable voids and seams, such as those illustrated in FIGS. 1A-1B, may cause device performance and reliability problems or even device failure.

FIG. 1A is a schematic cross-sectional view of a substrate 10A illustrating an undesirable void 20 formed during a conventional tungsten deposition process. Here, the substrate 10A includes a patterned surface 11 comprising a dielectric layer 12 having a high aspect ratio opening formed therein (shown filled with a portion of tungsten layer 15), a barrier material layer 14 deposited on the dielectric layer 12 to line the opening, and the tungsten layer 15 deposited on the barrier material layer 14. The tungsten layer 15 is formed using a conventional deposition process, e.g., a chemical vapor deposition (CVD) or atomic layer deposition (ALD) process where tungsten is conformally deposited (grown) on the patterned surface 11 to fill the opening. The tungsten layer 15 forms a tungsten feature 15A in the opening and an overburden of material (tungsten overburden layer 15B) on the field of the patterned surface 11.

In FIG. 1A, the opening has a non-uniform profile that is narrower at the surface of the substrate 10A and widens (bows outwardly) as the opening extends from the surface inwardly into the dielectric layer 12. As shown, overhanging portions of the conformal tungsten layer 15 have grown together to block or “pinch off” the entrance to the opening before the opening could be completely filled, thus causing the undesirable void 20, i.e., an absence of tungsten material, in the tungsten feature 15A. If the void 20 is opened (exposed) during the subsequent CMP process, polishing fluid may encroach into the tungsten feature 15A, and the chemically active components of the polishing fluid can cause further loss of the tungsten material therein, e.g., undesired feature coring (key-holing) through corrosion and/or static etch of the tungsten material. This undesirable tungsten loss may lead to device performance and reliability problems or, ultimately, to a complete failure of the device. Even without voiding, undesirable seaming in a tungsten feature is largely unavoidable using a conventional tungsten deposition process, such as shown in FIG. 1B.

FIG. 1B is a schematic cross-sectional view of a substrate 10B illustrating an undesirable seam 24 formed during a conventional tungsten deposition process. Here, the patterned surface 11 includes an opening (filled with a portion of tungsten layer 15) having a substantially uniform profile as the opening extends from the surface of the substrate 10B into the dielectric layer 12. The opening is filled with tungsten, and no void is formed. Nonetheless, conformal growth of the tungsten layer 15 outwardly from the walls of the opening has resulted in an undesirable seam 24 extending through the center of a tungsten feature 15A formed in the opening. Like the void 20 shown in FIG. 1A, the seam 24 is vulnerable to corrosion from the chemically active components of the tungsten polishing fluid, which may cause undesirable loss of tungsten material from the feature 15A if the seam 24 is exposed during the CMP process.

Fortunately, nascent technologies enabling selective tungsten deposition, thus providing for bottom-up tungsten gapfill, have shown promise in the formation of substantially void-free and seam-free features desired for the next generation of devices. Typically, bottom-up tungsten gapfill process schemes employ substrate treatment and tungsten deposition processes that are highly sensitive to even slight changes in substrate processing conditions. This process sensitivity non-uniformly affects the selectivity of tungsten deposition across the surface of a substrate and/or causes undesirable processing variation between multiple substrates processed within the same system over time or between substrates processed on different systems. Further, due (at least in part) to the high process sensitivity to any change in process conditions, different portions of the selective tungsten gapfill processes are often performed in different specialized and dedicated processing chambers, and the to-be-processed substrate is transferred one or more times therebetween.

Unfortunately, the specialized processing systems and substrate handling requirements for selective tungsten gapfill undesirably increase the time and cost of forming tungsten features when compared to conventional tungsten deposition processes. Accordingly, embodiments herein provide a processing system that is configured to perform a combination of the individual aspects of the methods without transferring a substrate between processing chambers, thus improving overall substrate processing throughput and capacity for the tungsten gapfill processing schemes described herein.

Generally, the gapfill processing schemes include forming a differential tungsten deposition inhibition profile in feature openings formed in a surface of a substrate, filling the openings with tungsten material according to the inhibition profile, and depositing an overburden of tungsten on the field surface of the substrate. Forming the tungsten deposition inhibition profile typically includes forming a tungsten nucleation layer and treating the tungsten nucleation layer using an activated nitrogen species, e.g., treatment radicals. The nitrogen treatment radicals are incorporated into portions of the nucleation layer, e.g., by adsorption of the nitrogen species and/or by reaction with the metallic tungsten of the nucleation layer to form tungsten nitride (WN). The adsorbed nitrogen and/or nitrided surface of the tungsten nucleation layer desirably delays (inhibits) tungsten nucleation and thus subsequent tungsten deposition thereon.

In some embodiments, the treatment radicals are formed remotely from a substrate processing chamber by use of a remote plasma source fluidly coupled thereto. The desired inhibition effect on the field of the patterned surface and the desired inhibition profile in the openings formed in the patterned surface is achieved by controlling processing conditions within the processing chamber, such as temperature and pressure, and controlling the concentration, flux, and energy of the treatment radicals at the substrate surface. Typically, the treatment radicals are formed from a non-halogen nitrogen-containing gas, such as N₂, NH₃, NH₄, or combinations thereof.

The tungsten nucleation and deposition processes of the gapfill processing scheme generally include flowing a tungsten-containing precursor and a reducing agent into the processing chamber and exposing the substrate surface thereto. The tungsten-containing precursor and the reducing agent react on the surface of the substrate in one of a chemical vapor deposition (CVD) process, a pulsed CVD process, an atomic layer deposition (ALD) process, or a combination thereof to deposit tungsten material thereon.

Inevitably, tungsten and tungsten-related species (undesirable tungsten residues) also deposit on surfaces in the processing chamber other than the substrate surface. If not removed, the tungsten residues are a source of defectivity (particles) that may cause device failure if transferred to a substrate surface. Thus, the processing systems described herein are configured to periodically perform a chamber cleaning operation where the undesired tungsten residues are removed from the interior surfaces of the processing chamber using a cleaning chemistry. Here, the cleaning chemistry comprises an activated halogen species, e.g., fluorine or chlorine (cleaning) radicals, formed remotely from the processing chamber.

The chamber cleaning operation generally includes flowing the halogen cleaning radicals into the processing chamber, reacting the cleaning radicals with the tungsten residue to form a volatile tungsten species, and evacuating the volatile tungsten species from the processing chamber through an exhaust. The chamber cleaning operation is typically performed between substrate processing, i.e., after a processed substrate has been removed from the processing chamber and before a subsequent to-be-processed processed substrate has been received into the processing chamber.

In some embodiments, the cleaning radicals are formed from a halogen-based cleaning gas, such as NF₃, using a remote plasma source fluidly coupled to the processing chamber. Forming the cleaning radicals remotely from the processing chamber desirably avoids ion-based damage to chamber components, such as erosion of surfaces within the processing chamber, which would otherwise occur if the cleaning radicals were formed therein by use of an in-situ plasma. Thus, ion-based damage may be desirably contained to plasma-facing surfaces within the remote plasma source, which may feature a halogen-based plasma resistant liner or coating to protect the underlying material from the corrosive effects of the halogen-based plasma.

In some embodiments, the remote plasma source used to form the treatment radicals used in the inhibition processes is also used to form the cleaning radicals used in the chamber cleaning process. Unfortunately, undesirable process variations in the resulting inhibition profiles have been observed when the same remote plasma source is used to provide radicals for both the inhibition treatment process and the chamber cleaning processes. The undesirable processing variability includes variations in inhibition profiles from substrate-to-substrate and/or non-uniform processing results across the surface of a substrate.

Without intending to be bound by theory, it is believed that at least some of the undesirable processing variation is the result of damage to surfaces within the remote plasma source caused by the halogen-based cleaning plasma. It is further believed that at least some processing variation is caused by nitrogen absorption and/or nitridation of the surfaces within the remote plasma source caused by exposure to the nitrogen-based treatment plasma. For example, it is believed that halogen-ion-based damage and/or accumulation of halogen-based contaminants on the plasma-facing surfaces of a remote plasma source adversely affect the dissociation and recombination rates of nitrogen treatment radicals subsequently formed therein. The variability in dissociation and recombination rates in treatment radicals formed using the remote cleaning plasma source may cause variability in the concentration, flux, and energy of activated nitrogen species at the substrate surface, leading to unstable processing results. Thus, the processing systems provided herein are configured with at least two remote plasma sources where a first remote plasma source is assigned and/or dedicated to generating treatment radicals, and a second remote plasma source is assigned and/or dedicated to generating cleaning radicals during chamber cleaning operations.

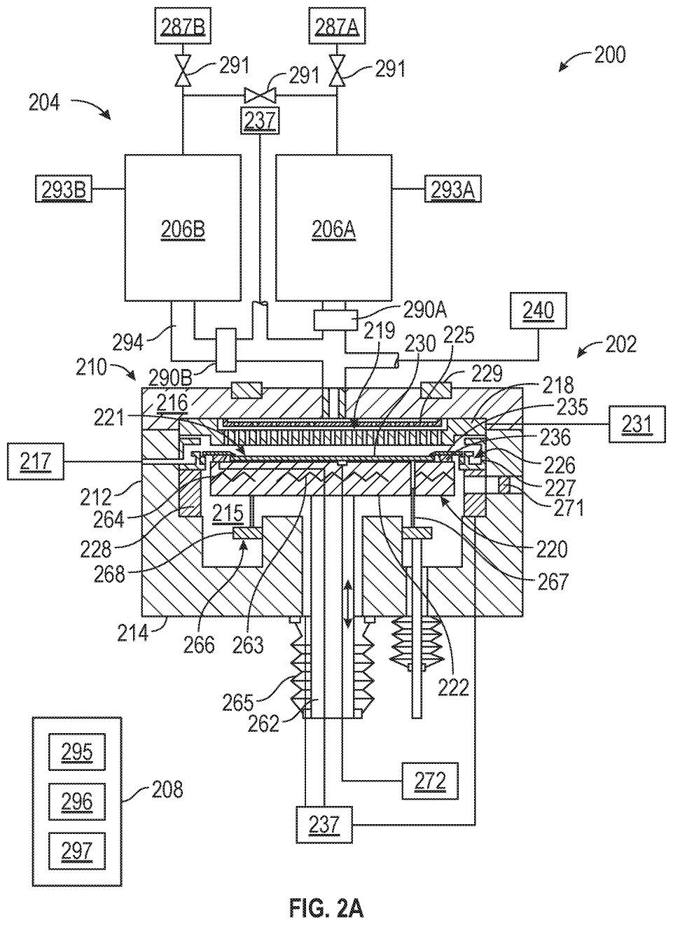

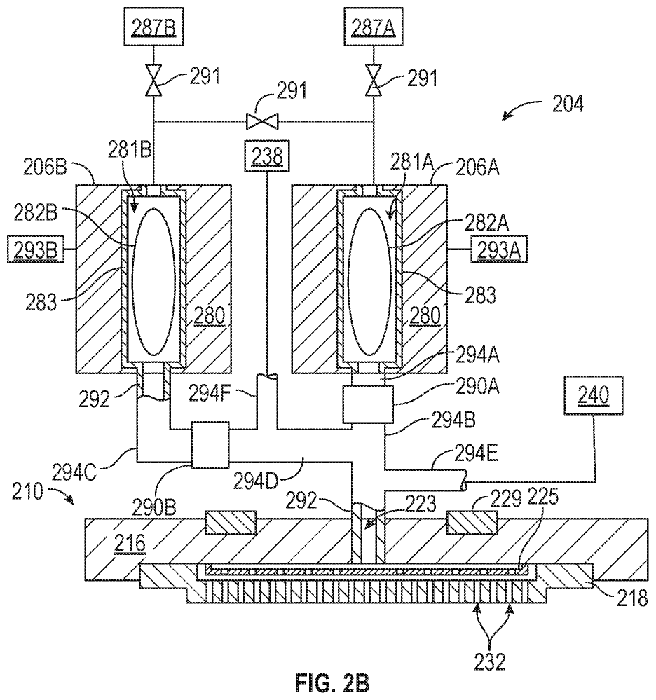

As discussed below, the use of assigned plasma sources for the respective inhibition and chamber cleaning processes provides improved processing stability for the inhibition treatments when compared to a processing system using a common plasma source for both. Thus, embodiments herein beneficially provide a relativity low-cost and high throughput, single-chamber solution for seam-suppressed tungsten gapfill, such as the processing system illustrated in FIGS. 2A-2B.

FIGS. 2A-2B schematically illustrate a processing system 200 that may be used to perform the bottom-up tungsten gapfill substrate processing methods described herein. Here, the processing system is configured to provide the different processing conditions desired for each of a nucleation process, inhibition treatment process, selective gapfill process, and overburden deposition process within a single processing chamber 202, i.e., without transferring a substrate between a plurality of processing chambers.

As shown in FIG. 2A, the processing system 200 includes a processing chamber 202, a gas delivery system 204 fluidly coupled to the processing chamber 202, and a system controller 208. The processing chamber 202 (shown in cross-section in FIG. 2A) includes a chamber lid assembly 210, one or more sidewalls 212, and a chamber base 214, which collectively define a processing volume 215. The processing volume 215 is fluidly coupled to an exhaust 217, such as one or more vacuum pumps, used to maintain the processing volume 215 at sub-atmospheric conditions and to evacuate processing gases and processing by-products therefrom.

The chamber lid assembly 210 includes a lid plate 216 and a showerhead 218 coupled to the lid plate 216 to define a gas distribution volume 219 therewith. Here, the lid plate 216 is maintained at a desired temperature using one or more heaters 229 thermally coupled thereto. The showerhead 218 faces a substrate support assembly 220 disposed in the processing volume 215. As discussed below, the substrate support assembly 220 is configured to move a substrate support 222, and thus a substrate 230 disposed on the substrate support 222, between a raised substrate processing position (as shown) and a lowered substrate transfer position (not shown). When the substrate support assembly 220 is in the raised substrate processing position, the showerhead 218 and the substrate support 222 define a processing region 221.

Here, the gas delivery system 204 is fluidly coupled to the processing chamber 202 through a gas inlet 223 (FIG. 2B) that is disposed through the lid plate 216. Processing or cleaning gases delivered, by use of the gas delivery system 204, flow through the gas inlet 223 into the gas distribution volume 219 and are distributed into the processing region 221 through a plurality of openings 232 (FIG. 2B) in the showerhead 218. In some embodiments, the chamber lid assembly 210 further includes a perforated blocker plate 225 disposed between the gas inlet 223 and the showerhead 218. In those embodiments, gases flowed into the gas distribution volume 219 are first diffused by the blocker plate 225 to, together with the showerhead 218, provide a more uniform or desired distribution of gas flow into the processing region 221.

Here, processing gases and processing by-products are evacuated radially outward from the processing region 221 through an annular channel 226 that surrounds the processing region 221. The annular channel 226 may be formed in a first annular liner 227 disposed radially inward of the one or more sidewalls 212 (as shown) or may be formed in the one or more sidewalls 212. In some embodiments, the processing chamber 202 includes one or more second liners 228, which are used to protect the interior surfaces of the one or more sidewalls 212 or chamber base 214 from corrosive gases and/or undesired material deposition.

In some embodiments, a purge gas source 237 in fluid communication with the processing volume 215 is used to flow a chemically inert purge gas, such as argon (Ar), into a region disposed beneath the substrate support 222, e.g., through the opening in the chamber base 214 surrounding the support shaft 262. The purge gas may be used to create a region of positive pressure below the substrate support 222 (when compared to the pressure in the processing region 221) during substrate processing. Typically, purge gas introduced through the chamber base 214 flows upwardly therefrom and around the edges of the substrate support 222 to be evacuated from the processing volume 215 through the annular channel 226. The purge gas reduces undesirable material deposition on surfaces beneath the substrate support 222 by reducing and/or preventing the flow of material precursor gases thereinto.

Here, the substrate support assembly 220 includes a movable support shaft 262 that sealingly extends through the chamber base 214, such as being surrounded by a bellows 265 in the region below the chamber base 214, and the substrate support 222, which is disposed on the movable support shaft 262. To facilitate substrate transfer to and from the substrate support 222, the substrate support assembly 220 includes a lift pin assembly 266 comprising a plurality of lift pins 267 coupled to or disposed in engagement with a lift pin hoop 268. The plurality of lift pins 267 are movably disposed in openings formed through the substrate support 222. When the substrate support 222 is disposed in a lowered substrate transfer position (not shown), the plurality of lift pins 267 extend above a substrate receiving surface of the substrate support 222 to lift a substrate 230 therefrom and provide access to a backside (non-active) surface of the substrate 230 by a substrate handler (not shown). When the substrate support 222 is in a raised or processing position (as shown), the plurality of lift pins 267 recede beneath the substrate receiving surface of the substrate support 222 to allow the substrate 230 to rest thereon.

Here, the substrate 230 is transferred to and from the substrate support 222 through a door 271, e.g., a slit valve disposed in one of the one or more sidewalls 212. Here, one or more openings in a region surrounding the door 271, e.g., openings in a door housing, are fluidly coupled to a purge gas source 237, e.g., an Ar gas source. The purge gas is used to prevent processing and cleaning gases from contacting and/or degrading a seal surrounding the door, thus extending the useful lifetime thereof.

Here, the substrate support 222 is configured for vacuum chucking where the substrate 230 is secured to the substrate support 222 by applying a vacuum to an interface between the substrate 230 and the substrate receiving surface. The vacuum is applied use of a vacuum source 272 fluidly coupled to one or more channels or ports formed in the substrate receiving surface of the substrate support 222. In other embodiments, e.g., where the processing chamber 202 is configured for direct plasma processing, the substrate support 222 may be configured for electrostatic chucking. In some embodiments, the substrate support 222 includes one or more electrodes (not shown) coupled to a bias voltage power supply (not shown), such as a continuous wave (CW) RF power supply or a pulsed RF power supply, which supplies a bias voltage thereto.

As shown, the substrate support assembly 220 features a dual-zone temperature control system to provide independent temperature control within different regions of the substrate support 222. The different temperature-controlled regions of the substrate support 222 correspond to different regions of the substrate 230 disposed of thereon. Here, the temperature control system includes a first heater 263 and a second heater 264. The first heater 263 is disposed in a central region of the substrate support 222, and the second heater 264 is disposed radially outward from the central region to surround the first heater 263. In other embodiments, the substrate support 222 may have a single heater or more than two heaters.

In some embodiments, the substrate support assembly 220 further includes an annular shadow ring 235, which is used to prevent undesired material deposition on a circumferential bevel edge of the substrate 230. During substrate transfer to and from the substrate support 222, i.e., when the substrate support assembly 220 is disposed in a lowered position (not shown), the shadow ring 235 rests on an annular ledge within the processing volume 215. When the substrate support assembly 220 is disposed in a raised or processing position, the radially outward surface of the substrate support 222 engages with the annular shadow ring 235 so that the shadow ring 235 circumscribes the substrate 230 disposed on the substrate support 222. Here, the shadow ring 235 is shaped so that a radially inward facing portion of the shadow ring 235 is disposed above the bevel edge of the substrate 230 when the substrate support assembly 220 is in the raised substrate processing position.

In some embodiments, the substrate support assembly 220 further includes an annular purge ring 236 disposed on the substrate support 222 to circumscribe the substrate 230. In those embodiments, the shadow ring 235 may be disposed on the purge ring 236 when the substrate support assembly 220 is in the raised substrate processing position. Typically, the purge ring 236 features a plurality of radially inward facing openings that are in fluid communication with the purge gas source 237. During substrate processing, a purge gas flows into an annular region defined by the shadow ring 235, the purge ring 236, the substrate support 222, and the bevel edge of the substrate 230 to prevent processing gases from entering the annular region and causing undesired material deposition on the bevel edge of the substrate 230.

In some embodiments, the processing chamber 202 is configured for direct plasma processing. In those embodiments, the showerhead 218 may be electrically coupled to a first power supply 231, such as an RF power supply, which supplies power to ignite and maintain a plasma of processing gases flowed into the processing region 221 through capacitive coupling therewith. In some embodiments, the processing chamber 202 comprises an inductive plasma generator (not shown), and a plasma is formed through inductively coupling an RF power to the processing gas.

Here, the processing system 200 is advantageously configured to perform each of the tungsten nucleation, inhibition treatment, and bulk tungsten deposition processes of a void-free and seam-free tungsten gapfill process scheme without removing the substrate 230 from the processing chamber 202. The gases used to perform the individual processes of the gapfill process scheme, and to clean residues from the interior surfaces of the processing chamber, are delivered to the processing chamber 202 using the gas delivery system 204 fluidly coupled thereto.

Generally, the gas delivery system 204 includes one or more remote plasma sources, here the first and second radical generator 206A-B, a deposition gas source 240, and a conduit system 294 (e.g., the plurality of conduits 294A-F) fluidly coupling the radical generators 206A-B and the deposition gas source 240 to the lid assembly 210. The gas delivery system 204 further includes a plurality of isolation valves, here the first and second valves 290A-B, respectively disposed between the radical generators 206A-B and the lid plate 216, which may be used to fluidly isolate each of the radical generators 206A-B from the processing chamber 202 and from one another.

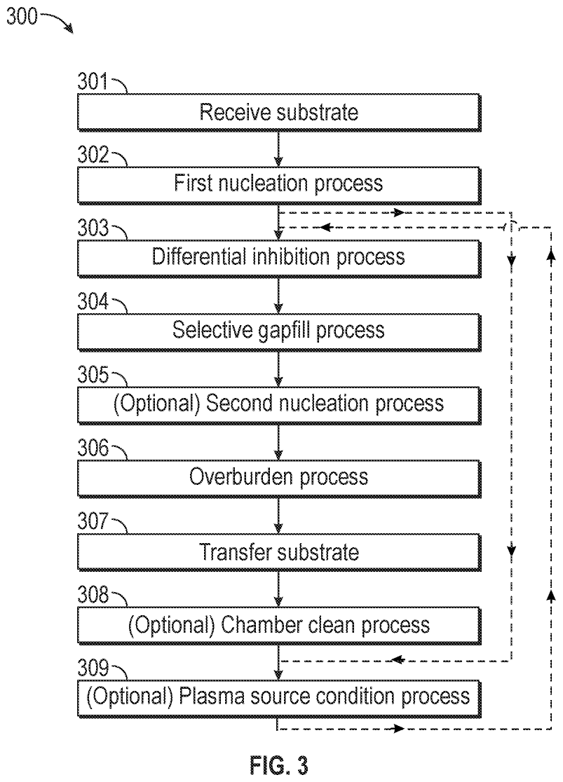

Here, each of the radical generators 206A-B features a chamber body 280 that defines the respective first and second plasma chamber volumes 281A-B (FIG. 2B). Each of the radical generators 206A-B is coupled to a respective power supply 293A-B. The power supplies 293A-B are used to ignite and maintain a plasma 282A-B of gases delivered to the plasma chamber volumes 281A-B from a corresponding first or second gas source 287A-B fluidly coupled thereto. In some embodiments, the first radical generator 206A generates radicals used in the differential inhibition process of activity 303 (FIG. 3). For example, the first radical generator 206A may be used to ignite and maintain a treatment plasma 282A from a non-halogen-containing gas mixture delivered to the first plasma chamber volume 281A from the first gas source 287A. The second radical generator 206B may be used to generate cleaning radicals used in a chamber clean process, e.g., activity 308 (FIG. 3) by igniting and maintaining a cleaning plasma 282B from a halogen-containing gas mixture delivered to the second plasma chamber volume 281B from the second gas source 287B.

Typically, nitrogen treatment radicals have a relativity short lifetime (when compared to halogen cleaning radicals) and may exhibit a relatively high sensitivity to recombination from collisions with surfaces in the gas delivery system 204 and/or with other species of the treatment plasma effluent. Thus, in embodiments herein, the first radical generator 206A is typically positioned closer to the gas inlet 223 than the second radical generator 206B, e.g., to provide a relatively shorter travel distance from the first plasma chamber volume 281A to the processing region 221.

In some embodiments, the first radical generator 206A is also fluidly coupled to the second gas source 287B, which delivers a halogen-containing conditioning gas to the first plasma chamber volume 281A to be used in a plasma source condition process, such as described in activity 309 of the method 300. In those embodiments, the gas delivery system 204 may further include a plurality of diverter valves 291, which are operable to direct the halogen-containing gas mixture from the second gas source 287B to the first plasma chamber volume 281A.

Suitable remote plasma sources which may be used for one or both of the radical generators 206A-B include radio frequency (RF) or very high radio frequency (VHRF) capacitively coupled plasma (CCP) sources, inductively coupled plasma (ICP) sources, microwave-induced (MW) plasma sources, electron cyclotron resonance (ECR) chambers, or high-density plasma (HDP) chambers.

As shown, the first radical generator 206A is fluidly coupled to the processing chamber 202 by use of first and second conduits 294A-B, which extend upwardly from the gas inlet 223 to connect with an outlet of the first plasma chamber volume 281A. A first valve 290A, disposed between the first and second conduits 294A-B, is used to selectively fluidly isolate the first radical generator 206A from the processing chamber 202 and the other portions of the gas delivery system 204. Typically, the first valve 290A is closed during the chamber clean process (activity 308) to prevent activated cleaning gases, e.g., halogen radicals, from flowing into the first plasma chamber volume 281A and damaging the surfaces thereof.

Here, the first radical generator 206A, the first and second conduits 294A-B, and the first valve 290A are arranged and/or configured so that the treatment plasma 282A is not disposed in a direct line-of-sight with the gas inlet 223, e.g., by having a bend in one or both of the conduits 294A-B. In other embodiments, the first plasma chamber volume 281A may be disposed in alignment with the gas inlet 223 to provide a direct line-of-sight from the treatment plasma 282A through the gas inlet 223 and into the processing chamber 202. The direct line-of-sight may beneficially reduce undesired recombination of the treatment radicals by reducing gas-phase collisions therebetween.

The second radical generator 206B is fluidly coupled to the second conduit 294B, and thus the processing chamber 202, by use of third and fourth conduits 294C-D. Here, the second radical generator 206B is selectively isolated from the processing chamber 202 and from the other portions of the gas delivery system 204 by use of a second valve 290B that is disposed between the third and fourth conduits 294C-D. As shown, the second radical generator 206B, the third and fourth conduits 294C-D, and the second valve 290B are arranged so that the cleaning plasma 282B is not disposed in a direct line-of-sight with the second valve 290B or the processing chamber 202. Blocking the direct line-of-sight between the cleaning plasma 282B and the second valve 290B and the cleaning plasma 282B and the processing chamber 202 prevents halogen ion-induced damage to the components of the second valve 290B and the processing chamber 202, thus desirably extending the useful lifetimes thereof.

In some embodiments, the plasma-facing surfaces 283 of one or both of the plasma chamber volumes 281A-B are formed of a halogen-based plasma resistant material, such as aluminum oxide, aluminum nitride, silicon oxide, fused silica, quartz, sapphire, or combinations thereof. In some embodiments, the plasma-facing surfaces 283 of the plasma chamber volumes 281A-B comprise a tube or a liner formed of the halogen-plasma resistant material. In other embodiments, the plasma-facing surfaces 283 feature a coating or layer of a halogen-based plasma resistant material formed on the interior portions of the chamber body 280, such as an anodized aluminum layer formed on the interior portions of an aluminum chamber body. In some embodiments, one or more of the conduits 294A-F are lined with a low recombination dielectric material 292, such as fused silica, quartz, or sapphire, which desirably reduces recombination of the activated species in the remote plasma effluents as they are delivered to the processing chamber 202.

Here, deposition gases, e.g., tungsten-containing precursors and reducing agents, are delivered from the deposition gas source 240 to the processing chamber 202 using a fifth conduit 294E. As shown, the fifth conduit 294E is coupled to the second conduit 294B at a location proximate to the gas inlet 223 so that the first and second valves 290A-B may be used to respectively isolate the first and second radical generators 206A-B from deposition gases introduced into the processing chamber 202. In some embodiments, the gas delivery system 204 further includes a sixth conduit 294F which is coupled to the fourth conduit 294D at a location proximate to the second valve 290B. The sixth conduit 294F is fluidly coupled to a bypass gas source 238, e.g., an argon (Ar) gas source, which may be used to periodically purge portions of the gas delivery system 204 of undesired residual cleaning, inhibition, and/or deposition gases.

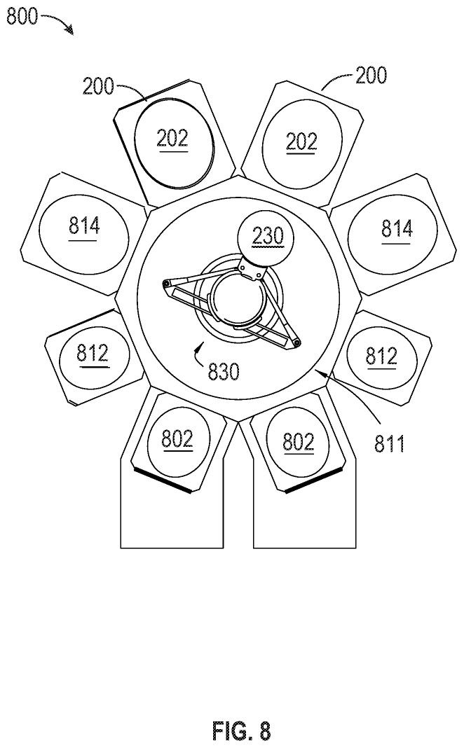

Operation of the processing system 200 is facilitated by the system controller 208. The system controller 208 includes a programmable central processing unit, here the CPU 295, which is operable with a memory 296 (e.g., non-volatile memory) and support circuits 297. The CPU 295 is one of any form of general-purpose computer processor used in an industrial setting, such as a programmable logic controller (PLC), for controlling various chamber components and sub-processors. The memory 296, coupled to the CPU 295, facilitates the operation of the processing chamber. The support circuits 297 are conventionally coupled to the CPU 295 and comprise cache, clock circuits, input/output subsystems, power supplies, and the like, and combinations thereof coupled to the various components of the processing system 200 (or the multi-chamber processing system 800 of FIG. 8) to facilitate control of substrate processing operations therewith.

Here, the instructions in memory 296 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

Advantageously, the processing system 200 described above may be used to perform each of the nucleation, inhibition, gapfill deposition, and overburden deposition processes of the method 300 set forth in FIG. 3, thus providing a single-chamber seam-free tungsten gapfill solution.

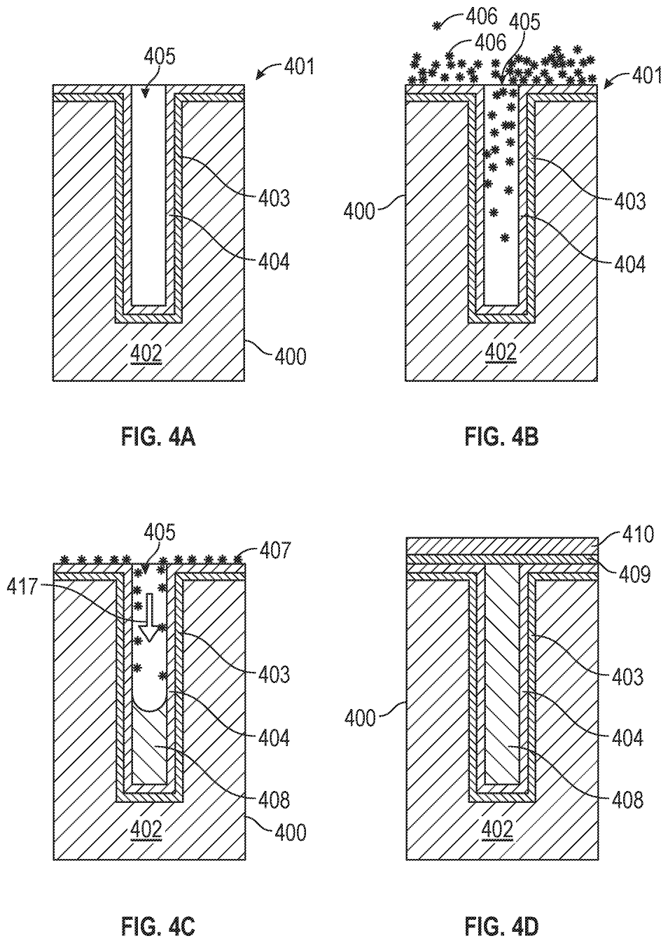

FIG. 3 is a diagram illustrating a method 300 of processing a substrate, according to an embodiment, which may be performed using the processing system 200. FIGS. 4A-4D are schematic sectional views of a portion of a substrate 400 illustrating aspects of the method 300 at different stages of a void-free and seam-free tungsten gapfill process scheme.

At activity 301, the method 300 includes receiving a substrate into a processing volume 215 of a processing chamber 202. At activity 302, the method 300 includes forming a nucleation layer 404 on the substrate using a nucleation process. A portion of an exemplary substrate 400 having the nucleation layer 404 formed thereon is schematically illustrated in FIG. 4A.

Here, the substrate 400 features a patterned surface 401 comprising a dielectric material layer 402 having a plurality of openings 405 (one shown) formed therein. In some embodiments, the plurality of openings 405 comprises one or a combination of high aspect ratio via or trench openings having a width of about 1 μm or less, such as about 800 nm or less, or about 500 nm or less, and a depth of about 2 μm or more, such as about 3 μm or more, or about 4 μm or more. In some embodiments, individual ones of the openings 405 may have an aspect ratio (depth to width ratio) of about 5:1 or more, such as about 10:1 or more, 15:1 or more, or between about 10:1 and about 40:1, such as between about 15:1 and about 40:1. As shown, the patterned surface 401 includes a barrier or adhesion layer 403, e.g., a titanium nitride (TIN) layer, deposited on the dielectric material layer 402 to conformally line the openings 405 and facilitate the subsequent deposition of the tungsten nucleation layer 404. In some embodiments, the adhesion layer 403 is deposited to a thickness of between about 2 angstroms (Å) and about 100 Å.

In some embodiments, the method 300 includes depositing the adhesion layer 403 using a second processing chamber of a multi-chamber processing system 800, such as illustrated in FIG. 8, before receiving the substrate into the processing chamber 202. In some embodiments, the method 300 includes sequentially depositing the adhesion layer 403 and the nucleation layer 404 in the same processing chamber 202. In some embodiments, the adhesion layer 403 functions as a nucleation layer enabling subsequent bulk tungsten deposition thereon. In embodiments where the adhesion layer 403 functions as a nucleation layer, the method 300 may not include activity 302.

In some embodiments, the nucleation layer 404 is deposited using an atomic layer deposition (ALD) process. Typically, the ALD process includes repeating cycles of alternately exposing the substrate 400 to a tungsten-containing precursor, exposing the substrate 400 to a reducing agent, and purging the processing region 221 between the alternating exposures. Examples of suitable tungsten-containing precursors include tungsten halides, such as tungsten hexafluoride (WF₆), tungsten hexachloride (WCl₆), or combinations thereof. Examples of suitable reducing agents include hydrogen gas (H₂), boranes, e.g., B₂H₆, and silanes, e.g., SiH₄, Si₂H₆, or combinations thereof. In some embodiments, the tungsten-containing precursor comprises WF₆, and the reducing agent comprises B₂H₆, SiH₄, or a combination thereof. In some embodiments, the tungsten-containing precursor comprises an organometallic precursor and/or a fluorine-free precursor, e.g., MDNOW (methylcyclopentadienyl-dicarbonylnitrosyl-tungsten), EDNOW (ethylcyclopentadienyl-dicarbonylnitrosyl-tungsten), tungsten hexacarbonyl (W(CO)6), or combinations thereof.

During the nucleation process, the processing volume 215 is typically maintained at a pressure of less than about 120 Torr, such as of between about 900 mTorr and about 120 Torr, between about 1 Torr and about 100 Torr, or for example, between about 1 Torr and about 50 Torr. Exposing the substrate 400 to the tungsten-containing precursor includes flowing the tungsten-containing precursor into the processing region 221 from the deposition gas source 240 at a flow rate of more than about 10 sccm, such as between about 10 sccm and about 1000 sccm, such as between about 10 sccm and about 750 sccm, or between about 10 sccm and about 500 sccm. Exposing the substrate 400 to the reducing agent includes flowing the reducing agent into the processing region 221 from the deposition gas source 240 at a flow rate of between about 10 sccm and about 1000 sccm, such as between about 10 sccm and about 750 sccm. It should be noted that the flow rates for the various deposition and treatment processes described herein are for a processing system 200 configured to process a 300 mm diameter substrate. Appropriate scaling may be used for processing systems configured to process different-sized substrates.

Here, the tungsten-containing precursor and the reducing agent are each flowed into the processing region 221 for a duration of between about 0.1 seconds and about 10 seconds, such as between about 0.5 seconds and about 5 seconds. The processing region 221 may be purged between the alternating exposures by flowing an inert purge gas, such as argon (Ar), into the processing region 221 for a duration of between about 0.1 seconds and about 10 seconds, such as between about 0.5 seconds and about 5 seconds. The purge gas may be delivered from the deposition gas source 240 or from the bypass gas source 238. Typically, the repeating cycles of the nucleation process continue until the nucleation layer 404 has a thickness of between about 10 Å and about 200 Å, such as between about 10 Å and about 150 Å, or between about 20 Å and about 150 Å.

At activity 303, the method 300 includes treating the nucleation layer 404 to inhibit tungsten deposition on a field surface of the substrate 400 and to form a differential inhibition profile in the plurality of openings 405 by use of a differential inhibition process. Typically, forming the differential inhibition profile includes exposing the nucleation layer 404 to the activated species of a treatment gas, e.g., the treatment radicals 406 shown in FIG. 4B. Suitable treatment gases that may be used for the inhibition process include N₂, H₂, NH₃, NH₄, O₂, CH₄, or combinations thereof. In some embodiments, the treatment gas comprises nitrogen, such as N₂, H₂, NH₃, NH₄, or a combination thereof, and the activated species comprise nitrogen radicals, e.g., atomic nitrogen. In some embodiments, the treatment gas is combined with an inert carrier gas, such as Ar, He, or a combination thereof, to form a treatment gas mixture.

Without intending to be bound by theory, it is believed that the activated nitrogen species (treatment radicals 406) are incorporated into portions of the nucleation layer 404 by adsorption of the activated nitrogen species and/or by reaction with the metallic tungsten of the nucleation layer 404 to form a tungsten nitride (WN) surface. The adsorbed nitrogen and/or nitrided surface of the tungsten nucleation layer 404 desirably delays (inhibits) further tungsten nucleation and thus subsequent tungsten deposition thereon.

Generally, diffusion of the treatment radicals 406 into the plurality of openings 405 is controlled to cause a desired inhibition gradient within the feature openings 405. Here, diffusion of the treatment radicals 406 is controlled so that the tungsten growth inhibition effect decreases on the walls of the openings 405 with increasing distance from the field of the patterned surface 401 (FIGS. 4B-4C). As a result, tungsten nucleation is more easily established at locations at or near the bottom of the feature, and once established, tungsten growth (deposition of the gapfill material 408) within the openings 405 accelerates from the point of nucleation (e.g., from regions of no or low inhibition at the bottom of the opening 405) to provide for a bottom-up seamless tungsten gapfill. The direction of the inhibition gradient, from regions of higher inhibition to regions of no or lower inhibition, is shown by arrow 417 (FIG. 4C). Diffusion of the treatment radicals 406 into the openings 405 typically depends, at least in part, on the size and aspect ratios of the openings 405 and may be adjusted by controlling inter alia, the energy, flux, and, in some embodiments, the directionality of the treatment radicals 406 at the patterned surface 401.

In some embodiments, exposing the nucleation layer 404 to the treatment radicals 406 includes forming a treatment plasma 282A of a substantially halogen-free treatment gas mixture using the first radical generator 206A and flowing the effluent of the treatment plasma 282A into the processing region 221. In some embodiments, a flow rate of the treatment gas mixture into the first radical generator 206A, and thus the flow rate of the treatment plasma effluent into the processing region 221, is between about 1 sccm and about 3000 sccm, such as between about 1 sccm and about 2500 sccm, between about 1 sccm and about 2000 sccm, between about 1 sccm and about 1000 sccm, between about 1 sccm and about 500 sccm, between about 1 sccm and about 250 sccm between about 1 sccm and about 100 sccm, or between about 1 sccm and about 75 sccm, for example, between about 1 sccm and about 50 sccm.

In some embodiments, a flow rate of the treatment gas mixture into the first radical generator 206A is between about 50 sccm and about 3000 sccm, such as between about 50 sccm and about 2500 sccm, between about 50 sccm and about 2000 sccm, between about 50 sccm and about 1000 sccm, between about 50 sccm and about 500 sccm, or between about 50 sccm and about 250 sccm. In some embodiments, a flowrate of the substantially halogen-free treatment gas, e.g., N₂, is between about 1 sccm and about 200 sccm, such as between about 1 sccm and about 100 sccm, and a flowrate of the inert carrier gas is between about 50 sccm and about 3000 sccm, such as between about 50 sccm and about 2000 sccm, or between about 100 sccm and about 2000 sccm.

In some embodiments, the inhibition treatment process includes exposing the substrate 400 to the treatment radicals 406 for a period of about 5 seconds or more, such as about 6 seconds or more, about 7 seconds or more, about 8 seconds or more, about 9 seconds or more, about 10 second or more, or between about 5 seconds and about 120 seconds, such as between about 5 seconds and about 90 seconds, or between about 5 seconds and about 60 seconds, or between about 5 seconds and about 30 seconds, for example, between about 5 seconds and about 20 seconds.

In some embodiments, a concentration of the substantially halogen-free treatment gas in the treatment gas mixture is between about 0.5 vol. % and about 50 vol. %, such as between about 0.5 vol. % and about 40 vol. %, between about 0.5 vol. % and about 30 vol. %, about 0.5 vol. % and about 20 vol. %, or, for example, between about 0.5 vol. % and about 10 vol. %, such as between about 0.5 vol. % and about 5 vol. %.

In some embodiments, e.g., where the substantially halogen-free treatment gas comprises N₂, NH₃, and/or NH₄, the first radical generator 206A may be used to activate between about 0.02 mg and about 150 mg of atomic nitrogen during an inhibition treatment process for a 300 mm diameter substrate, such as between about 0.02 mg and about 150 mg, or between about 0.02 mg and about 100 mg, between about 0.1 mg and about 100 mg, between about 0.1 mg and about 100 mg, or between about 1 mg and about 100 mg. In some embodiments, the first radical generator 206A may be used to activate about 0.02 mg of atomic nitrogen or more during an inhibition treatment process for a 300 mm diameter substrate, such as about 0.2 mg or more, about 0.4 mg or more, about 0.6 mg or more, about 0.8 mg or more, about 1 mg or more, about 1.2 mg or more, about 1.4 mg or more, about 1.6 mg or more, about 1.8 mg or more, about 2 mg or more, about 2.2 mg or more, about 2.4 mg or more, about 2.6 mg or more, about 2.8 mg, or about 3 mg or more. Appropriate scaling may be used for processing systems configured to process different sized substrates.

In other embodiments, the treatment radicals 406 may be formed using a remote plasma (not shown) which is ignited and maintained in a portion of the processing volume 215 that is separated from the processing region 221 by the showerhead 218, such as between the showerhead 218 and the lid plate 216. In those embodiments, the activated treatment gas may be flowed through an ion filter to remove substantially all ions therefrom before the treatment radicals 406 reach the processing region 221 and the surface of the substrate 400. In some embodiments, the showerhead 218 may be used as the ion filter. In other embodiments, a plasma used to form the treatment radicals is an in-situ plasma formed in the processing region 221 between the showerhead 218 and the substrate 400. In some embodiments, e.g., when using an in-situ treatment plasma, the substrate 400 may be biased to control the directionality and/or accelerate ions formed from the treatment gas, e.g., charged treatment radicals, towards the substrate surface.

In some embodiments, the inhibition treatment process includes maintaining the processing volume 215 at a pressure of less than about 100 Torr while flowing the activated treatment gas thereinto. For example, during the inhibition treatment process, the processing volume 215 may be maintained at a pressure of less than about 75 Torr, such as less than about 50 Torr, less than about 25 Torr, less than about 15 Torr, or between about 0.5 Torr and about 120 Torr, such as between about 0.5 Torr and about 100 Torr, or between about 0.5 Torr and about 50 Torr, or for example, between about 1 Torr and about 10 Torr.

At activity 304, the method 300 includes selectively depositing a tungsten gapfill material 408 (FIGS. 4C-4D) into the plurality of openings 405 according to the differential inhibition profile provided by the inhibition treatment at activity 303. In one embodiment, the tungsten gapfill material 408 is formed using a low-stress chemical vapor deposition (CVD) process comprising concurrently flowing (co-flowing) a tungsten-containing precursor gas, and a reducing agent into the processing region 221 and exposing the substrate 400 thereto. The tungsten-containing precursor and the reducing agent used for the tungsten gapfill CVD process may comprise any combination of the tungsten-containing precursors and reducing agents described in activity 301. In some embodiments, the tungsten-containing precursor comprises WF₆, and the reducing agent comprises H₂.

Here, the tungsten-containing precursor is flowed into the processing region 221 at a rate of between about 50 sccm and about 1000 sccm, or more than about 50 sccm, or less than about 1000 sccm, or between about 100 sccm and about 900 sccm. The reducing agent is flowed into the processing region 221 at a rate of more than about 500 sccm, such as more than about 750 sccm, more than about 1000 sccm, or between about 500 sccm and about 10000 sccm, such as between about 1000 sccm and about 9000 sccm, or between about 1000 sccm and about 8000 sccm.

In some embodiments, the tungsten gapfill CVD process conditions are selected to provide a tungsten feature having a relativity low residual film stress when compared to conventional tungsten CVD processes. For example, in some embodiments, the tungsten gapfill CVD process includes heating the substrate to a temperature of about 250° C. or more, such as about 300° C. or more, or between about 250° C. and about 600° C., or between about 300° C. and about 500° ° C. During the CVD process, the processing volume 215 is typically maintained at a pressure of less than about 500 Torr, less than about 600 Torr, less than about 500 Torr, less than about 400 Torr, or between about 1 Torr and about 500 Torr, such as between about 1 Torr and about 450 Torr, or between about 1 Torr and about 400 Torr, or for example, between about 1 Torr and about 300 Torr.

In another embodiment, the tungsten gapfill material 408 is deposited at activity 304 using an atomic layer deposition (ALD) process. The tungsten gapfill ALD process includes repeating cycles of alternately exposing the substrate 400 to a tungsten-containing precursor gas and a reducing agent and purging the processing region 221 between the alternating exposures. The tungsten-containing precursor and the reducing agent used for the tungsten gapfill ALD process may comprise any combination of the tungsten-containing precursors and reducing agents described in activity 301. In some embodiments, the tungsten-containing precursor comprises WF₆, and the reducing agent comprises Hz.

Here, the tungsten-containing precursor and the reducing agent are each flowed into the processing region 221 for a duration of between about 0.1 seconds and about 10 seconds, such as between about 0.5 seconds and about 5 seconds. The processing region 221 is typically purged between the alternating exposures by flowing an inert purge gas, such as argon (Ar), into the processing region 221 for a duration of between about 0.1 seconds and about 10 seconds, such as between about 0.5 seconds and about 5 seconds. The purge gas may be delivered from the deposition gas source 240 or from the bypass gas source 238.

Exposing the substrate 400 to the tungsten-containing precursor may include flowing the tungsten-containing precursor into the processing region 221 from the deposition gas source 240 at a flow rate of between about 10 sccm and about 1000 sccm, such as between about 100 sccm and about 1000 sccm, between about 200 sccm and about 1000 sccm, between about 400 sccm and about 1000 sccm, or between about 500 sccm and about 900 sccm. Exposing the substrate 400 to the reducing agent may include flowing the reducing agent into the processing region 221 from the deposition gas source 240 at a flow rate of between about 500 sccm and about 10000 sccm, such as between about 500 sccm and about 8000 sccm, between about 500 sccm and about 5000 sccm, or between about 1000 sccm and about 4000 sccm.

In some embodiments, the tungsten gapfill ALD process includes heating the substrate to a temperature of about 250° C. or more, such as about 300° C. or more, or between about 250° C. and about 600° ° C., or between about 300° C. and about 500° C. In some embodiments, the ALD process includes maintaining the processing volume 215 at a pressure of less than about 150 Torr, less than about 100 Torr, less than about 50 Torr, for example, less than about 30 Torr, or between about 0.5 Torr and about 50 Torr, such as between about 1 Torr and about 20 Torr.

In other embodiments, the tungsten gapfill material 408 is deposited using a pulsed CVD method that includes repeating cycles of alternately exposing the substrate 400 to a tungsten-containing precursor gas and a reducing agent without purging the processing region 221. The processing conditions for the tungsten gapfill pulsed CVD method may be the same, substantially the same, or within the same ranges as those described above for the tungsten gapfill ALD process.

Beneficially, the tungsten gapfill processes described above provide for a relativity low residual stress in the tungsten material formed therefrom. Without intending to be bound by theory, it is believed that the increased energy provided by the relatively high substrate temperature, e.g., 250° C. or more, increases adatom diffusivity to open adsorption sites while the relativity low processing pressure concurrently slows the tungsten gapfill deposition process. The increased adatom diffusivity and reduced deposition rate facilitate improved (more ordered) atomic arrangement in the deposited tungsten material when compared to conventional conformal CVD processes, beneficially resulting in lower residual film stress in the tungsten gapfill material. For example, in some embodiments, a blanket tungsten layer deposited to a thickness of about 1,200 Å using processing conditions described above has a residual film stress of less than about 1600 MPa, less than about 1500 MPa, less than about 1400 MPa, less than about 1300 MPa, less than about 1200 MPa, less than about 1100 MPa, less than about 1000 MPa, less than about 900 MPa, less than about 800 MPa, less than about 700 MPa, or, in some embodiments, less than about 600 MPa.

In a typical semiconductor manufacturing scheme, a chemical mechanical polishing (CMP) process may be used to remove an overburden of tungsten material (and the barrier layer disposed there below) from the field surface of the substrate following depositing the tungsten gapfill material 408 into the opening 405. CMP processes generally rely on a combination of chemical and mechanical activity to facilitate uniform removal of the overburden layer 410 and an endpoint detection method to determine when the tungsten overburden has cleared from the field surface. Non-uniform clearing of tungsten from the field surface or failure to detect a polishing endpoint can result in undesired over-polishing or under-polishing of at least some regions of the substrate surface. Tungsten over-polishing can cause undesired removal of tungsten from the tungsten feature, e.g., feature coring, because the polishing fluid in a CMP process is often corrosive and can cause damage to the features during over-polishing. Tungsten under-polishing can result in undesired residual tungsten remaining on the field surface following CMP.

Unfortunately, the inhibition treatments used to provide seam-free and void-free tungsten features by promoting bottom-up growth of tungsten also inhibit the growth of tungsten on the field surface to prevent a uniform overburden of tungsten from forming during the bulk tungsten process. Thus, the embodiments herein may include processes for depositing an overburden layer, which are different from the process used to deposit the tungsten gapfill material 408, to provide a uniform thickness of tungsten on the field surface of the substrate desired for subsequent CMP processing.

At activity 305, the method 300 optionally includes forming a second nucleation layer 409 (FIG. 4D) using a second nucleation process. At activity 306, the method 300 includes forming an overburden layer 410 using an overburden process. The second nucleation process and/or the overburden process are used to reduce and/or eliminate the tungsten growth inhibition on the field surface of the substrate, which was provided by the inhibition treatment process at activity 303. By reducing and/or reversing the inhibition effect, the field surface is prepared to allow for the growth and/or deposition of an overburden of tungsten material. The overburden layer 410 may be used to facilitate uniform processing in a subsequent chemical mechanical polishing (CMP) process.

In some embodiments, the second nucleation layer 409 is deposited using an ALD process that is the same or substantially similar to the ALD process used to form the (first) nucleation layer 404 at activity 302, or an ALD process having processing conditions which are in the ranges recited for the ALD process at activity 302. When used, the second nucleation layer 409 may be deposited to a thickness of between about 5 Å and 100 Å, or between about 10 Å and 80 Å, or for example, between about 20 Å and 60 Å.

The process used to deposit the overburden layer 410 at activity 306 may be a CVD or ALD process that is the same or substantially similar to the CVD or ALD process used to deposit the gapfill tungsten material at activity 304, or a process having processing conditions which are in the ranges recited for the processes at activity 302. In other embodiments, the overburden layer is deposited using a CVD process having a processing pressure that is greater than the processing pressure used for the tungsten gapfill process at activity 302. For example, in some embodiments, a ratio of the processing pressure used to deposit the overburden layer 410 to a processing pressure used to deposit the tungsten gapfill material 408 is about 1.25:1 or more, such as about 1.5:1 or more, about 1.75:1 or more, about 2:1 or more, about 2.25:1 or more, about 2.5:1 or more, about 2.75:1 or more, about 3:1 or more, about 3.25:1 or more, or about 3.5:1 or more. The increased processing pressure of the overburden process advantageously results in increased deposition rates and reduced substrate processing time. Here, the overburden layer is deposited to a thickness of between about 500 Å and about 6000 Å, such as between about 1000 Å and about 5000 Å.

At activity 307, the method 300 includes transferring the processed substrate 400 out of the processing chamber 202 and resumes at activity 301 by receiving a to-be-processed substrate thereinto 202. In some embodiments, the method 300 further includes periodically cleaning the processing chamber 202 between processing substrates by use of the chamber clean process at activity 308. The chamber clean process is used to remove undesirable process residue, e.g., accumulated tungsten residue, from the interior surfaces of the processing volume 215. In some embodiments, the chamber clean process is performed after a number of substrates sequentially processed in the processing chamber 202 is greater than or equal to a threshold value, such as greater than or equal to 2 substrates or more, 3 substrates or more, 5 substrates or more, 7 substrates or more, 9 substrates or more, or 11 substrates or more.

At activity 308 of the method 300, the chamber clean process generally includes activating a cleaning gas in a remote plasma source, and flowing the activated cleaning gas into the processing chamber 202. Typically, the cleaning gas mixture includes a halogen-containing gas and a carrier gas, such as argon or helium. Examples of suitable halogen-containing gases which may be used in the cleaning gas mixture include NF₃, F₂, SF₆, CL₂, CF₄, C₂F₆, C₄F₈, CHF₃, CF₆, CCl₄, C₂Cl₆, and combinations thereof. In some embodiments, the cleaning gas further comprises a diluent gas, such as Ar, He, or combinations thereof. For example, in one embodiment, the cleaning gas mixture comprises NF₃ and Ar or He. Typically, the activated species of the cleaning gas mixture, e.g., halogen radicals, react with tungsten residue accumulated on surfaces of the processing chamber 202 to form a volatile tungsten species. The volatile tungsten species are evacuated from the processing volume 215 through the exhaust 217.

In some embodiments, a flow rate of the cleaning gas mixture into the remote plasma source, and thus a flow rate of the activated cleaning gas mixture into the processing volume 215, is about 500 sccm or more, such as about 1000 sccm or more, 1500 sccm or more, about 2000 sccm or more, or about 2500 sccm or more. The concentration of halogen-containing gas in the cleaning gas mixture is typically between about 5 vol. % and about 95 vol. %, such as between about 5 vol. % and about 70 vol. %, about 10 vol. % and about 95 vol. %, or more than about 10 vol. %.

In some embodiments, the activated cleaning gas mixture is flowed into the processing volume 215 for a duration of about 5 seconds or more, about 10 seconds or more, about 15 seconds or more. In some embodiments of the chamber cleaning process, the remote plasma source may be used to activate about 5 mg or more of an atomic halogen, e.g., fluorine or chlorine, such as about 10 mg or more, about 15 mg or more, about 20 mg or more, about 25 mg or more, about 30 mg or more, about 35 mg or more, about 40 mg or more, about 45 mg or more, or, for example, about 50 mg or more for a processing chamber sized for processing 300 mm diameter substrates. Appropriate scaling may be used for processing chambers sized to process different sized substrates.

Here, the chamber clean process is performed using a remote plasma source (e.g., the second radical generator 206B), which is different from the remote plasma source used to generate the treatment radicals (e.g., the first radical generator 206A) at activity 303. For example, here, the chamber clean process includes flowing the cleaning gas mixture into the second radical generator 206B, igniting and maintaining a cleaning plasma 282B of the cleaning gas mixture, and flowing the effluent of the cleaning plasma 282B into the processing volume 215. Generally, performing the chamber cleaning operation after each substrate processed in the processing chamber 202 is undesirable due to the lost substrate processing capacity associated therewith. Thus, the chamber cleaning operation is typically performed after a plurality of substrates have been processed in the chamber so that an average number of substrates processed between chamber cleaning operations is about 2 substrates or more, such as about 5 substrates or more, about 10 substrates or more, about 15 substrates or more, or about 20 substrates or more.

The use of a dedicated plasma source (first radical generator 206A) for the inhibition treatment process at activity 303 desirably provides for improved processing stability for the inhibition treatments over the use of a common plasma source for both the inhibition treatment process and chamber cleaning process. This is likely because a plasma formed from the treatment gas is substantially less corrosive than a plasma formed from a halogen-based cleaning gas, and thus, ion-based damage to surfaces within the first radical generator 206A is relativity low. Nonetheless, in time at least some drift in processing performance at the substrate edge, e.g., a degradation of inhibition performance at the substrate edge, has been observed when using a treatment plasma source dedicated to forming nitrogen treatment radicals.

Without intending to be bound by theory, it is believed that the activated nitrogen species may be adsorbed in the plasma-facing surfaces of the remote plasma source and in surfaces of conduits between the remote plasma source and the processing chamber and/or cause the nitridation thereof. The adsorbed nitrogen and/or nitrided surfaces 407 may reduce the treatment plasma efficiency, e.g., reduce the dissociation rate of the treatment gas and/or promote the recombination of activated nitrogen species exposed thereto, thus resulting in reduced radical concentration and flux at the substrate surface. Thus, in some embodiments, the first radical generator 206A is periodically conditioned by igniting and maintaining a plasma from a relatively low flow and/or concentration of a halogen-containing gas to remove adsorbed nitrogen and/or nitridation from the surfaces therein, as described in activity 309. The plasma source conditioning process is used to activate surfaces of the first radical generator 206A in order to extend the lifetime of treatment radicals subsequently formed therein. Generally, extending the lifetime of the treatment radicals allows for an increase in the number of substrates that may be processed between chamber cleaning processes.

In FIG. 3, the plasma source condition process is shown as being performed after a processed substrate is transferred from the processing chamber 202 and before a subsequent to-be-processed substrate is received thereinto. In other embodiments, the plasma source condition process may be performed while a substrate is positioned on the substrate support 222, e.g., before the differential inhibition process at activity 303 (as shown by the dashed line), after the differential inhibition process at activity 303, or before, after, or concurrent with any of the respective nucleation, gapfill, and overburden processes at activities 302, 304, 305, and 306.

At activity 309, the method 300 includes flowing a conditioning gas mixture into the first radical generator 206A and activating the conditioning gas mixture by igniting and maintaining a plasma thereof. Here, the conditioning gas mixture comprises a halogen-containing gas and an inert carrier gas, such as Ar, He, or a combination thereof. Suitable halogen-containing gases which may be used in the conditioning gas mixture are described at activity 308. In some embodiments, the halogen-containing gas comprises NF₃.

In some embodiments, the halogen-containing gas comprises between about 0.1 vol. % and about 50 vol. % of the conditioning gas mixture, such as about 0.1 vol. % and about 40 vol. %, about 0.1 vol. % and about 30 vol. %, about 0.1 vol. % and about 25 vol. %, or, for example 0.1 vol. % and about 25 vol. %. The conditioning gas mixture is flowed into the first radical generator 206A at a flow rate of between about 100 sccm and about 2000 sccm, and a plasma of the conditioning gas mixture is ignited and maintained for a period of between about 1 seconds and about 30 seconds, or about 1 second or more, or about 30 seconds or less. In some embodiments, the halogen-containing gas may be introduced into the first radical generator 206A at an effective flow rate of between about 0.1 sccm and about 30 sccm, such as between about 0.1 sccm and about 20 sccm, between about 0.1 sccm and about 10 sccm, or between about 0.1 sccm and about 5 sccm. Here, the effective flow rate is equal to the flow rate of the conditioning gas mixture times the vol. % of the halogen-containing gas.

In some embodiments, the first radical generator 206A may be used to activate between about 0.002 mg and about 40 mg of atomic halogen, such as fluorine or chlorine, during a plasma source condition process, such as between about 0.002 mg and about 35 mg, or between about 0.02 mg and about 30 mg, between about 0.02 mg and about 25 mg, between about 0.02 mg and about 20 mg, or between about 0.02 mg and about 15 mg. In some embodiments, the first radical generator 206A may be used to activate at least about 0.02 mg of an atomic halogen and no more than about 40 mg during the plasma source condition process, such as no more than about 35 mg, no more than about 30 mg, no more than about 25 mg, no more than about 20 mg, no more than about 15 mg, no more than about 10 mg, or at least about 0.02 mg and no more than about 8 mg of the atomic halogen.

In some embodiments, it may be desirable to limit the amount of halogen radicals that the interior surfaces of the first radical generator 206A are exposed to between plasma inhibition treatment processes. In those embodiments, a weight ratio of the activated halogen species generated in the first radical generator 206A, e.g., during the plasma source condition process, to the activated nitrogen radicals generated in a subsequent inhibition treatment process (fluorine (mg)/nitrogen (mg) or chlorine (mg)/nitrogen (mg)) may be no more than about 5:1, such as no more than about 4:1, no more than about 3:1, or no more than about 2:1, such as no more than about 1:1.

As discussed above, the plasma source condition process beneficially improves processing stability from substrate-to-substrate and within-substrate processing uniformity. Without intending to be bound by theory, it is believed that the activated nitrogen species used in the inhibition treatment process absorb on the surface of conduits between the source and chamber, and the nitrided surfaces promote recombination rate of activated nitrogen species subsequently flowed therethrough. The plasma source condition process beneficially removes nitrogen species from the surface between substrates and hence helps lower recombination rate as well as extend the lifetime of treatment radicals.

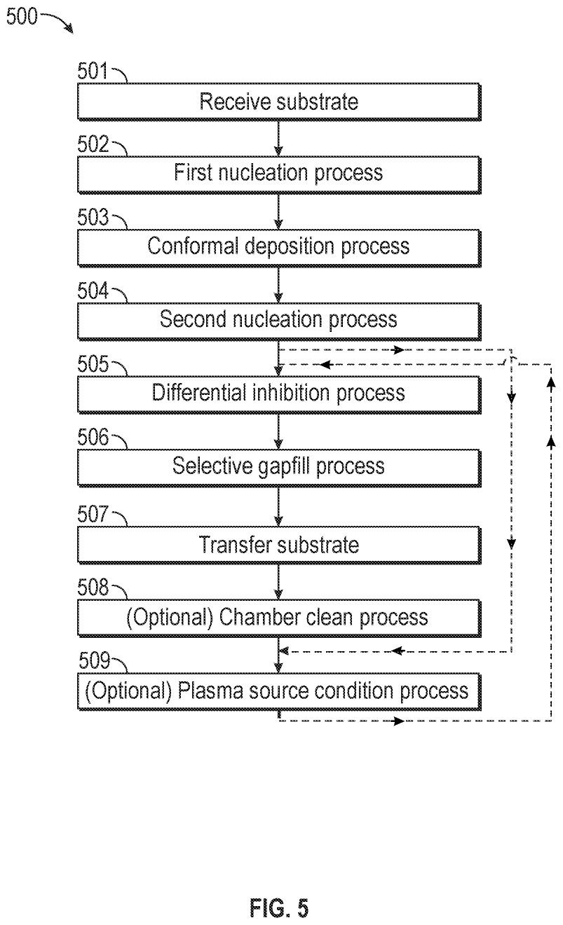

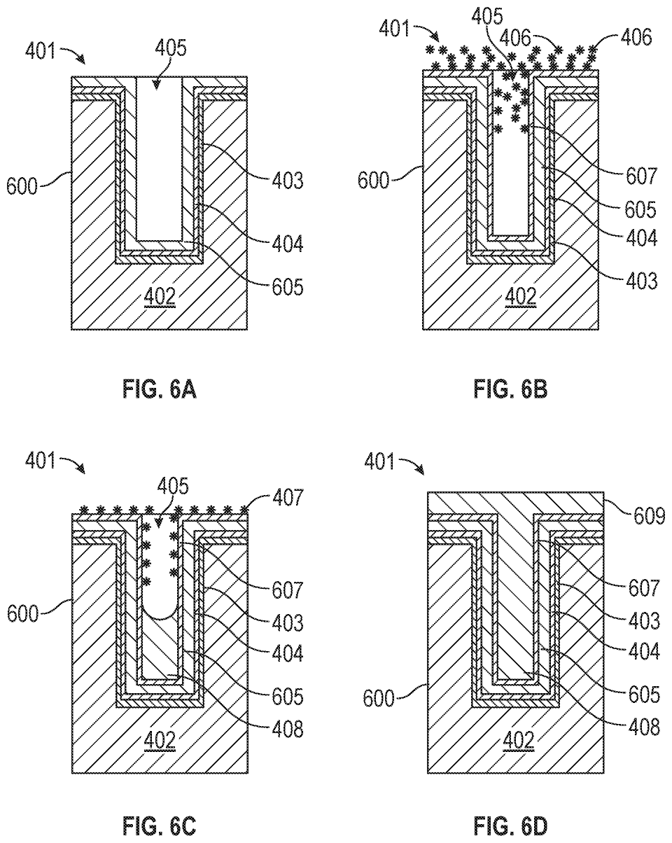

FIG. 5 is a diagram illustrating a method 500 of processing a substrate, according to another embodiment, which may be performed using the processing system 200 described in FIGS. 2A-2B. It is contemplated that any one of the activities and/or processing conditions described in the method 500 may be combined with, or used in place of, the activities and/or processing conditions described in the method 300. FIGS. 6A-6D are schematic sectional views of a portion of a substrate 400 illustrating various aspects of the method 500 at different stages of a void-free and seam-free tungsten gapfill process scheme. FIG. 6A schematically illustrates the substrate 600 after the performance of activities 501-503 of the method 500.

At activity 501, the method 500 includes receiving the substrate 600 into the processing volume 215 of the processing chamber 202. The substrate 600 features a patterned surface 401 comprising a dielectric material layer 402 having a plurality of openings 405 (one shown) formed therein and may include any one of the features and/or attributes of the substrate 400 described in FIGS. 4A-4D, such as the conformal adhesion layer 403.

At activity 502, the method 500 includes depositing a first nucleation layer 404. The first nucleation layer 404 may be deposited using the nucleation process described in activity 302 of the method 300.

At activity 503, the method 500 includes depositing a conformal tungsten layer 605 on the first nucleation layer 404. The conformal tungsten layer 605 may be deposited using the process and/or processing conditions of any one or combination of the low-stress CVD, ALD, or pulsed CVD processes described in the selective gapfill process of activity 304. Here, the tungsten layer 605 is deposited onto an uninhibited tungsten nucleation layer 404 and thus may conform to the patterned surface 401 of the substrate 600, e.g., to conformally line the openings 405 formed therein. In some embodiments, the conformal tungsten layer 605 may be deposited to a thickness of more than about 50 angstroms (Å), such as between about 50 Å and about 1000 Å, or between about 50 Å and about 500 Å.

At activity 504, the method 500 includes depositing a second nucleation layer 607 (FIG. 6B) on the conformal tungsten layer 605. In some embodiments, the second nucleation layer 607 is formed using the same process, or a different process within the same range of processing conditions, as used to form the first nucleation layer 404.

At activity 505, the method 500 includes treating the second nucleation layer 607 to inhibit tungsten deposition on a field surface of the substrate 600 and to form a differential inhibition profile in the plurality of openings 405 by use of a differential inhibition process. Activity 505 is illustrated in FIG. 6B and may be performed using any one of the processes or processing conditions described in activity 303 of the method 300.

In some embodiments, the method 500 includes performing a plasma source conditioning process (activity 509) after forming the second nucleation layer 607 at activity 504 and before performing the inhibition treatment at activity 505. In those embodiments, the stacked layers of the first nucleation layer 404, the conformal tungsten layer 605, and the second nucleation layer 607 may protect the underlying surfaces from etching and/or damage caused by exposure to the effluent (halogen radicals) of the plasma source conditioning process.

At activity 506, the method 500 includes selectively depositing a bulk tungsten fill material 408 (FIGS. 6C-6D) into the plurality of openings 405 according to the differential inhibition profile provided by the inhibition treatment at activity 505. Activity 506 may be performed using any one or combination of the processes or processing conditions as used for the selective gapfill process described in activity 304 of the method 300.

At activity 507, the method 500 includes transferring the substrate 600 out of the processing chamber 202 and, in some embodiments, transferring a to-be-processed substrate into the processing chamber 202 and repeating the method 500.

In some embodiments, the method 500 further includes performing a chamber cleaning process at activity 508 and/or performing a plasma source condition process at activity 509. Activities 508 and 509 may be performed using any one or combination of the processes, processing conditions, and/or order of operations, respectively described in activities 308 and 309 of the method 300.

In some embodiments, the method 500 further includes forming an overburden layer 609 of tungsten material on the field surface of the substrate 600. In some embodiments, forming the overburden layer 609 comprises continuing the gapfill process at activity 506 until the inhibition effect on the field surface is overcome, and tungsten material may be deposited thereon. In other embodiments, the overburden layer 609 may be formed using one or a combination of the processes described in activities 305 and 306 of the method 300.

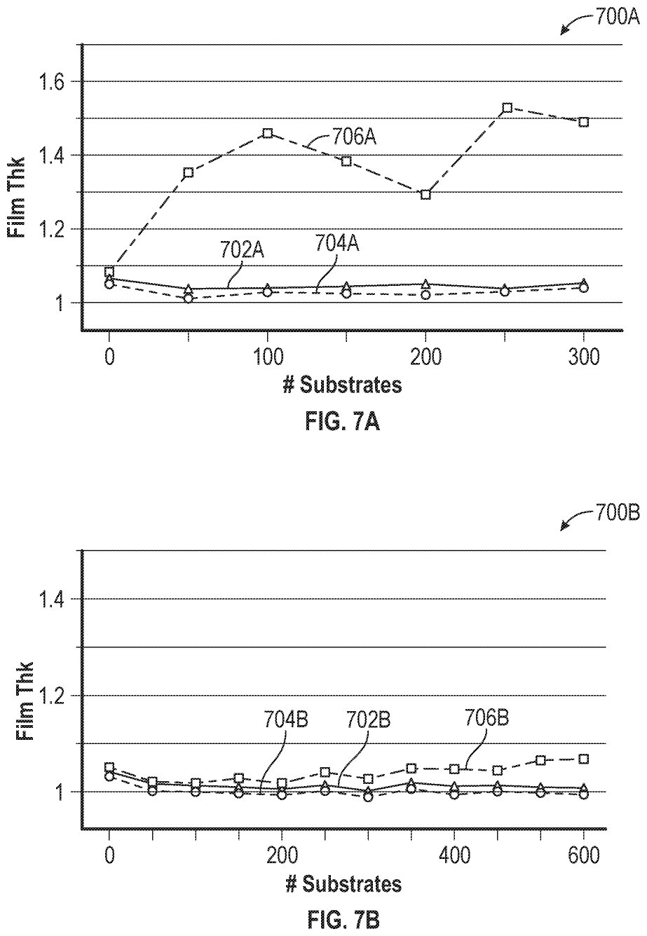

The methods and systems provided above may be used to desirably reduce substrate-to-substrate process variability and improve within-substrate processing uniformity while concurrently providing for increased substrate processing throughput and decreased substrate processing costs. The increased processing stability and improved within-substrate processing uniformity provided by the systems and methods above demonstrated by the experimental results shown in FIGS. 7A-7B.

FIG. 7A is a graph 700A illustrating processing results for a plurality of substrates processed on a processing system without the use of the plasma source condition process described in activities 309 and 509. FIG. 7B is a graph 700B illustrating processing results for a plurality of substrates processed using the plasma source conditioning process described in activities 309 and 509. In each of FIGS. 7A-7B, a plurality of 300 mm diameter substrates, each having a tungsten nucleation layer formed thereon, were exposed to nitrogen treatment radicals formed using a dedicated remote plasma source, e.g., the first radical generator 206A, before a layer of tungsten was subsequently deposited thereon using a tungsten gapfill process, such as described in activity 304.

In FIG. 7A, a plurality of substrates (300 substrates) were sequentially processed without the use of a plasma source condition process so that the first radical generator 206A was not exposed to a halogen-containing cleaning gas between inhibition treatment processes. In FIG. 7B, a plurality of substrates (600 substrates) were sequentially processed using the same conditions as used for the substrates of FIG. 7A, except the remote plasma source (first radical generator 206A) was conditioned using the plasma source condition process of activity 309 between each of the inhibition treatments. Measurements of the resulting tungsten thickness were taken at the center of each substrate, and at radiuses of 50 mm (lines 702A-B), 100 mm (lines 704A-B), and 147 mm (lines 706A-B). The tungsten thickness measurements taken at the center of each substrate are not shown in order to reduce visual clutter but were within about +/−2.5% of the thickness measurements at radiuses of 50 mm (lines 702A-B) and 100 mm (lines 704A-B).

As can be seen in FIG. 7A, the inhibition effect at the edge of the substrate 706A (as shown by the thickness of tungsten material deposited thereon) decreases over the course of the first 50 sequentially processed substrates while the inhibition effect at regions radially inward from the edge remains relativity stable from substrate-to-substrate. In contrast, in FIG. 7B, the inhibition effect at the edge of the substrate 706B compared to the regions 702B and 704B radially inward therefrom remains relatively stable for over 600 sequentially processed substrates.

In a typical processing system 200, where the gas inlet 223 is centrally located through the lid plate 216, the activated nitrogen species used to treat the substrate edge travel a greater distance to reach the substrate surface than the activated species used to treat the surfaces regions disposed radially inward from the substrate edge. Without intending to be bound by theory, it is believed that the greater travel distance may result in a reduced excitation of the activated species or increased recombination of the activated species at the substrate edge. The undesirably reduced concentration and flux of treatment radicals at the substrate edge is believed to cause a corresponding reduction in the inhibition effect received therefrom. Thus, it is believed that the improvement in within substrate uniformity and reduced substrate-to-substrate processing variability demonstrated in FIGS. 7A-7B is the result of an increase in radical lifetime and/or the generation of at least metastable radical species that is enabled by the plasma source condition process. In embodiments herein, a metastable radical species is a radical, e.g., nitrogen treatment radical, which has a lifetime of about 3 seconds or more.

In some embodiments, the methods described above may be performed using a multi-chamber processing system 800, such as illustrated in FIG. 8. Here, the multi-chamber processing system 800 includes a plurality of system loading stations, here load lock stations 802, for receiving substrates. The load lock stations 802 may be sealed and are typically coupled to a vacuum, such as one or more vacuum pumps, which may be used to evacuate gases therefrom and maintain the load lock stations 802 at sub-atmospheric conditions. A substrate handler 830, disposed in a transfer chamber 811, is used to move substrates 230 between the load lock stations 802 and one or more processing chambers 812, 814, 202. Each processing chamber 812 and 814, may be configured to perform at least one of a substrate deposition process, such as cyclical layer deposition (CLD), atomic layer deposition (ALD), chemical vapor deposition (CVD), physical vapor deposition (PVD), etch, degas, pre-cleaning orientation, anneal, and other substrate processes. The processing systems 200 are described in FIGS. 2A-2B and are configured to perform the tungsten gapfill processing schemes described herein.

Advantageously, the processing systems 200, 800 described above are configured to accommodate the different processing conditions desired for each of the nucleation, inhibition, gapfill deposition, and overburden deposition processes within a single processing chamber 202 without removing the substrate therefrom. The processing systems 200 are further configured to reduce processing variability, e.g., within-substrate processing non-uniformity and substrate-to-substrate processing variation, thus providing for desirably wider processing windows to achieve void-free, seam-free and/or low-stress tungsten features.

While the foregoing is directed to embodiments of the present disclosure, other and further embodiments of the disclosure may be devised without departing from the basic scope thereof, and the scope thereof is determined by the claims that follow.

44019396WO01 Reference Numbers

| | |
|---|---|
| patterned surface | 11 |
| dielectric layer | 12 |
| barrier material layer | 14 |
| tungsten layer | 15 |
| void | 20 |
| seam | 24 |
| processing system | 200 |
| processing chamber | 202 |
| gas delivery system | 204 |
| system controller | 208 |
| lid assembly | 210 |
| sidewalls | 212 |
| chamber base | 214 |
| processing volume | 215 |
| lid plate | 216 |
| exhaust | 217 |
| showerhead | 218 |
| gas distribution volume | 219 |
| substrate support assembly | 220 |
| processing region | 221 |
| substrate support | 222 |
| gas inlet | 223 |
| blocker plate | 225 |
| annular channel | 226 |
| first annular liner | 227 |
| second liners | 228 |
| heaters | 229 |
| substrate | 230 |
| first power supply | 231 |
| openings | 232 |
| shadow ring | 235 |
| purge ring | 236 |
| purge gas source | 237 |
| gas source | 238 |
| deposition gas source | 240 |
| support shaft | 262 |
| first heater | 263 |
| second heater | 264 |
| bellows | 265 |
| pin assembly | 266 |
| pins | 267 |
| pin hoop | 268 |
| door | 271 |
| vacuum source | 272 |
| chamber body | 280 |
| plasma-facing surfaces | 283 |
| diverter valves | 291 |
| dielectric material | 292 |
| conduit system | 294 |
| CPU | 295 |
| memory | 296 |
| support circuits | 297 |
| method | 300 |
| activity | 301 |
| activity | 302 |
| activity | 303 |
| activity | 304 |
| activity | 305 |
| activity | 306 |
| activity | 307 |
| activity | 308 |
| activity | 309 |
| substrate | 400 |
| patterned surface | 401 |
| dielectric material layer | 402 |
| adhesion layer | 403 |
| first nucleation layer | 404 |
| openings | 405 |
| treatment radicals | 406 |
| surfaces | 407 |
| gapfill material | 408 |
| second nucleation layer | 409 |
| layer | 410 |
| arrow | 417 |
| method | 500 |
| activity | 501 |
| activity | 502 |
| activity | 503 |
| activity | 504 |
| activity | 505 |
| activity | 506 |
| activity | 507 |
| activity | 508 |
| activity | 509 |
| tungsten layer | 605 |
| second nucleation layer | 607 |
| layer | 609 |
| multi-chamber processing system | 800 |
| load lock stations | 802 |
| transfer chamber | 811 |
| processing chambers | 812 |
| processing chambers | 814 |
| substrate handler | 830 |
| substrate | 10A |
| substrate | 10B |
| feature | 15A |
| layer | 15B |
| first radical generator | 206A |
| second radical generator | 206B |
| first plasma chamber volume | 281A |
| second plasma chamber volume | 281B |
| treatment plasma | 282A |
| cleaning plasma | 282B |
| first gas source | 287A |
| second gas source | 287B |
| first valve | 290A |
| second valve | 290B |
| power supplies | 293A-B |
| conduits | 294A-F |
| graph | 700A |
| graph | 700B |
| lines | 702A |
| lines | 702B |
| lines | 704A-B |
| substrate | 706A |
| substrate | 706B |

What is claimed is:

1. A substrate processing system, comprising:
a processing chamber, comprising a chamber lid assembly, one or more chamber sidewalls, and a chamber base that collectively define a processing volume;
a gas delivery system fluidly coupled to the processing chamber, the gas delivery system comprising a first radical generator and a second radical generator; and
a non-transitory computer readable medium having instructions stored thereon for performing a method of processing a plurality of substrates when executed by a processor, the method comprising:
(a) receiving a substrate into the processing volume;
(b) exposing the substrate to an activated treatment gas, the activated treatment gas comprising an effluent of a treatment plasma formed in the first radical generator;
(c) exposing the substrate to a first tungsten-containing precursor and a first reducing agent to deposit a tungsten gapfill material;
(d) transferring the substrate out of the processing volume;
(e) before or after (a), conditioning the first radical generator, comprising:
i. flowing a conditioning gas into the first radical generator, the conditioning gas comprising a halogen-based component; and
ii. igniting and maintaining a conditioning plasma of the conditioning gas for a first period of time; and
(f) repeating (a)-(e) when a number of sequentially processed substrates is less than or equal to a threshold value.

2. The processing system of claim 1, the method further comprising:
(g) exposing chamber surfaces in the processing volume to an activated cleaning gas when the number of sequentially processed substrates is greater than or equal to the threshold value, the activated cleaning gas comprising an effluent of a cleaning plasma formed in the second radical generator; and
(h) repeating (a)-(g).

3. The processing system of claim 2, wherein the treatment plasma is formed of a halogen free nitrogen-containing gas and a weight ratio of halogen radicals generated during (e) to nitrogen radicals generated in the first radical generator during (b) is no more than about 5:1.

4. The processing system of claim 2, wherein a flow rate of the halogen-based component into the first radical generator is less than about 10 sccm.

5. The processing system of claim 1, the method further comprising:
after (a) and before (b), forming a first tungsten nucleation layer.

6. The processing system of claim 5, the method further comprising:
before (b), forming a conformal tungsten layer on the first tungsten nucleation layer; and
forming a second tungsten nucleation layer on the conformal tungsten layer.

7. The processing system of claim 5, wherein
the substrate comprises a material layer having a plurality of openings formed therein, and
exposing the substrate to the activated treatment gas differentially inhibits tungsten deposition on a field surface of the substrate relative to surfaces within the plurality of openings.

8. The processing system of claim 5, wherein the forming the first tungsten nucleation layer comprises repeating cycles of alternately exposing the substrate the first or a second tungsten-containing precursor and the first or a second reducing agent.

9. The processing system of claim 2, wherein the gas delivery system further comprises:
a first valve fluidly coupled between the first radical generator and the processing chamber; and
a second valve fluidly coupled between the second radical generator and the processing chamber, wherein
exposing the chamber surfaces to the activated cleaning gas comprises fluidly isolating the first radical generator from the effluent of the cleaning plasma by use of the first valve.

10. The processing system of claim 9, wherein exposing the substrate to the activated treatment gas comprises fluidly isolating the second radical generator from the effluent of the treatment plasma by use of the second valve.

11. A method of processing a substrate, comprising:
(a) receiving the substrate into a processing volume of a processing system, the processing system comprising:
a processing chamber comprising a chamber lid assembly, one or more chamber sidewalls, and a chamber base that collectively define the processing volume; and
a gas delivery system fluidly coupled to the processing chamber, the gas delivery system comprising a first radical generator and a second radical generator;
(b) exposing the substrate to an activated treatment gas, the activated treatment gas comprising an effluent of a treatment plasma formed in the first radical generator;
(c) exposing the substrate to a first tungsten-containing precursor and a first reducing agent;
(d) transferring the substrate out of the processing volume; and
(e) before or after (a), conditioning the first radical generator, comprising:
i. flowing a conditioning gas into the first radical generator, the conditioning gas comprising a halogen-based component; and
ii. igniting and maintaining a conditioning plasma of the conditioning gas for a first period of time; and
(f) repeating (a)-(e) when a number of sequentially processed substrates is less than or equal to a threshold value.

12. The method of claim 11, further comprising:
(g) exposing chamber surfaces in the processing volume to an activated cleaning gas when the number of sequentially processed substrates is greater than or equal to the threshold value, the activated cleaning gas comprising an effluent of a cleaning plasma formed in the second radical generator; and
(h) repeating (a)-(g).

13. The method of claim 12, wherein the treatment plasma is formed of a halogen free nitrogen-containing gas and a weight ratio of halogen radicals generated during (e) to nitrogen radicals generated in the first radical generator during (b) is no more than about 5:1.

14. The method of claim 12, wherein a flow rate of the halogen-based component into the first radical generator is less than about 10 sccm.

15. The method of claim 11, further comprising:
after (a) and before (b), forming a first tungsten nucleation layer.

16. The method of claim 15, further comprising:
before (b), forming a conformal tungsten layer on the first nucleation layer; and
forming a second nucleation layer on the conformal tungsten layer.

17. The method of claim 15, wherein
the substrate comprises a material layer having a plurality of openings formed therein, and
exposing the substrate to the activated treatment gas differentially inhibits tungsten deposition on a field surface of the substrate relative to surfaces within the plurality of openings.

18. The method of claim 12, wherein the gas delivery system further comprises:
a first valve fluidly coupled between the first radical generator and the processing chamber; and
a second valve fluidly coupled between the second radical generator and the processing chamber, wherein
exposing the chamber surfaces to the activated cleaning gas comprises fluidly isolating the first radical generator from the cleaning plasma effluent by use of the first valve, and
exposing the substrate to the activated treatment gas comprises fluidly isolating the second radical generator from the treatment plasma effluent by use of the second valve.

19. The method of claim 18, wherein the lid assembly comprises a lid plate and a showerhead coupled to the lid plate, and the first and second radical generator are in fluid communication with the processing volume through a gas inlet formed through the lid plate.

20. The method of claim 19, wherein the effluent of the treatment plasma travels a first distance from the first radical generator to the processing volume and the effluent of the cleaning plasma effluent a second distance from the second radical generator to the processing volume, and the first distance is less than the second distance.
